(19) United States
(12) Patent Application Publication
(10) Pub. No.: US 2024/0120423 A1
(43) Pub. Date: Apr. 11, 2024

(54) SEMICONDUCTOR DEVICE

(71) Applicant: WILL SEMICONDUCTOR (SHANGHAI) CO. LTD., Shanghai (CN)

(72) Inventors: TETSUYA OKADA, SAITAMA (JP); KIKUO OKADA, SAITAMA (JP); REMI HAGIWARA, GUNMA (JP)

(21) Appl. No.: 18/073,356

(22) Filed: Dec. 1, 2022

(30) Foreign Application Priority Data
Oct. 7, 2022 (JP) 2022162428

(51) Int. Cl. H01L 29/872; H01L 21/225; H01L 21/265; H01L 21/304; H01L 21/66; H01L 29/47; H01L 29/66

(52) U.S. Cl. CPC H01L 29/872; H01L 21/2253; H01L 21/26513; H01L 21/304; H01L 22/12; H01L 29/47; H01L 29/66143

(57) ABSTRACT

A semiconductor device includes a semiconductor substrate; an anode electrode, formed on a surface on one side of the semiconductor substrate; a cathode electrode, formed on a surface on the other side of the semiconductor substrate; a P layer, formed on the anode electrode side in the semiconductor substrate; and an N layer, formed on the cathode electrode side in the semiconductor substrate and on the other side of the P layer. The cathode electrode and the N layer are Schottky functioned, the cathode electrode is a metal having work function ranging from 4.2 to 4.3, and the carrier concentration of the N layer ranges from 1×e¹² to 1×e¹⁸/cm³.

### BACKGROUND OF THE INVENTION

### 1. Field of the Invention

The disclosure relates to a semiconductor device, and particularly, to reduction of recovery loss.

### 2. Description of the Related Art

Current control using a PN junction has recently been used in a semiconductor device. For example, a diode has a PN junction, allows a current flowing from an anode on a P side to a cathode on an N side, and blocks a current flowing in an opposite direction. And, during conduction, a large quantity of carriers, that is, holes from the anode and electrons from the cathode, are injected, and a forward voltage drop VF during conduction is lowered.

On the other hand, during recovery, the injected holes and electrons (carriers) are respectively discharged into the anode and the cathode, so that a recovery loss Err is increased if there are a large quantity of carriers.

In Patent document 1, it is shown that a lifetime killer is set up to eliminate internal carriers, thereby speeding up the discharge of the carriers.

### PRIOR ART DOCUMENTS

### Patent Documents

[Patent document 1] International Publication No. WO2017/146148

### SUMMARY OF THE INVENTION

### Problems to be Solved

Here, a lifetime killer is set up by forming a semiconductor crystal defect, and hence large-scale apparatuses and work processes are required for this purpose.

### Means to Solve Problems

A semiconductor device according to the disclosure includes: a semiconductor substrate; an anode electrode, formed on a surface on one side of the semiconductor substrate; a cathode electrode, formed on a surface on the other side of the semiconductor substrate; a P layer, formed on the anode electrode side in the semiconductor substrate; and an N layer, formed on the cathode electrode side in the semiconductor substrate and on the other side of the P layer. The cathode electrode and the N layer are Schottky-junctioned, the cathode electrode is a metal having work function ranging from 4.2 to 4.3, and the carrier concentration of the N layer ranges from 1×e¹² to 1×e¹⁸/cm³.

### Effects

According to the semiconductor device related to the disclosure, a structure with low injection of electrons and long lifetime can be obtained without using a lifetime killer.

### BRIEF DESCRIPTION OF THE DRAWINGS

FIG. 1 is a schematic diagram showing a configuration of a semiconductor device according to an embodiment.

FIG. 2 shows voltage and current waveforms of a general diode during recovery.

FIG. 3 is a diagram showing a relationship between a recovery loss Err and a forward voltage drop VF of a general diode during recovery based on the work function.

FIG. 4 is a schematic diagram showing an injection state of holes and electrons in a semiconductor device 10 according to the embodiment.

FIG. 5 is a diagram showing an energy level of Schottky junction.

FIG. 6 is a diagram showing a current waveform of the semiconductor device 10 according to the embodiment during recovery.

FIG. 7 is a diagram showing an electron density of the semiconductor device 10 in a depth direction during conduction.

FIG. 8 is a characteristic diagram showing the dependence of the recovery loss Err and the forward voltage drop VF on the work function of a metal.

FIG. 9 is a characteristic diagram showing the dependence of the recovery loss Err and the forward voltage drop VF on a doping carrier concentration of an N-type carrier (impurity) in an N layer.

FIG. 10 is a diagram showing a relationship between the recovery loss Err and the forward voltage drop VF of the semiconductor device 10 according to the embodiment during recovery.

FIG. 11 is a diagram showing a manufacturing process of the semiconductor device according to the embodiment.

### PREFERRED EMBODIMENT OF THE PRESENT INVENTION

Hereinafter, embodiments of the disclosure are described with reference to the drawings. Note that, the following embodiments do not limit the scope of the disclosure, and configurations obtained by selectively combining multiple examples are also included in the disclosure.

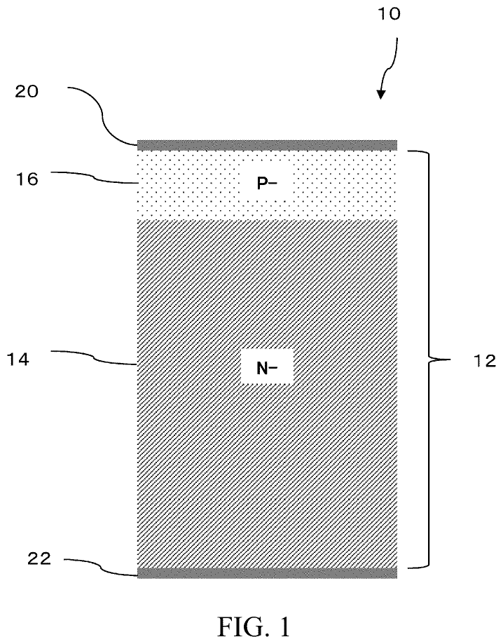

“Configuration of semiconductor device” FIG. 1 is a schematic diagram showing a configuration of a semiconductor device according to an embodiment. The semiconductor device 10 includes a semiconductor substrate 12. The semiconductor substrate 12 includes, for example, a silicon (Si) wafer, but can also be another semiconductor such as SiC or gallium oxide. In addition, in the embodiment, an N-type FZ wafer is used which is formed by using a FZ (floating zone) method and in which an N-type carrier (impurity) is doped.

Because the N-type wafer is used as the semiconductor substrate 12, a large part of the semiconductor substrate 12 directly becomes an N layer 14. The N layer 14 is generally referred to as the N-drift layer. A P layer 16 is formed on one side of the N layer 14 by doping a P-type carrier (impurity) from a surface on one side.

In addition, an anode electrode 20 is formed on the surface of the semiconductor substrate 12 on one side, that is, on the P layer 16. The anode electrode 20 may be formed by a metal such as aluminum.

A cathode electrode 22 is formed on a surface (back surface) of the semiconductor substrate 12 on the other side, that is, on a surface (back surface) of the N layer 14 on the other side. The cathode electrode 22 can also be formed by a metal as the anode electrode 20.

In this way, in the embodiment, the cathode electrode 22 is in direct contact with the N layer 14, and the cathode electrode 22 and the N layer 14 are Schottky functioned. Moreover, the metal of the cathode electrode 22 can be aluminum (Al) or an aluminum-silicon alloy (Al—Si alloy), and the cathode electrode 22 can be formed by using aluminum (Al) or an aluminum-silicon alloy (Al—Si alloy) as a main component.

In addition, regarding the work function of the cathode electrode 22, a metal having work function ranging from 4.2 to 4.3, such as the foregoing metal, is used. In addition, the carrier concentration of the N layer 14 is set within a range of 1×e¹² to 1×e¹⁸/cm³. That is, the semiconductor substrate 12 is not limited to silicon, and may be SiC, gallium oxide, or the like, and the cathode electrode 22 is not limited to aluminum or an aluminum alloy, but should be selected in a manner that a difference between the work functions of the semiconductor substrate 12 and the cathode electrode 22 is 4.2 to 4.3.

According to this way, the quantity of electrons injected from the cathode electrode 22 side to the N layer 14 can be appropriately controlled, the recovery loss can be suppressed, and a forward voltage drop VF of the semiconductor device 10, which is used as a diode in this example, can be maintained relatively small.

The semiconductor device 10 according to the embodiment can be directly used as a diode, and can be used in various elements in which a diode is incorporated.

“Recovery Waveform”

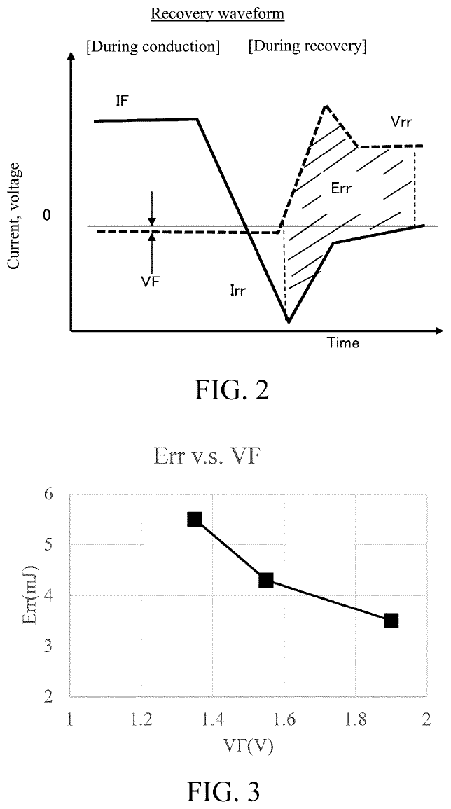

FIG. 2 is a diagram showing voltage and current waveforms of a general diode during recovery. First, during conduction, the voltage between the anode electrode 20 and the cathode electrode is the forward voltage drop VF, and the voltage becomes a predetermined small voltage in a state that there are sufficient P-type and N-type carriers, and a predetermined current IF flows. In this example, voltage Vrr is a cathode voltage.

Here, the current IF linearly decreases by applying a reverse voltage. This is implemented by withdrawing holes from the N layer 14 to the anode electrode 20 via the P layer 16 and withdrawing electrons to the cathode electrode 22. In this case, the current Irr significantly fluctuates to a negative side once and then becomes close to 0, and the cathode voltage Vrr significantly fluctuates to a positive side and then becomes stable at an applied voltage.

The energy loss during recovery is Vrr*Irr*time, and the loss from when Vrr becomes positive to when Irr becomes 0 is a recovery loss Err.

FIG. 3 is a diagram showing a relationship between the recovery loss Err and the forward voltage drop VF of a general diode during recovery. In this way, the forward voltage drop VF increases when the carrier concentration decreases. On the other hand, there is a trade-off relationship in which when the carrier concentration is high, there are more residual carriers during recovery and the recovery loss increases.

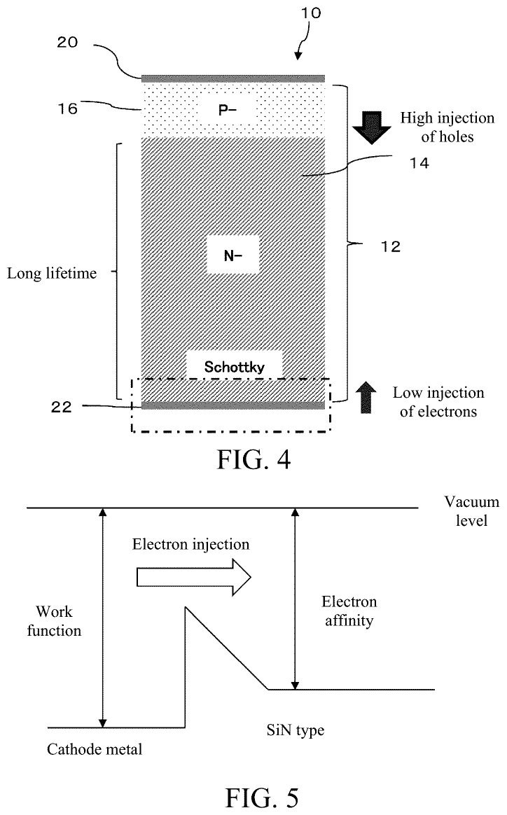

FIG. 4 is a schematic diagram showing an injection state of holes and electrons in the semiconductor device 10 according to the embodiment. In this way, the electron injection quantity is suppressed by the Schottky junction between the cathode electrode 22 and the N layer 14. Thus, a structure with low injection of electrons and long lifetime can be obtained without using a lifetime killer.

FIG. 5 is a diagram showing an energy level of Schottky junction. By the Schottky junction according to this way, an energy barrier is formed, and thus the injection of electrons into a semiconductor side is suppressed.

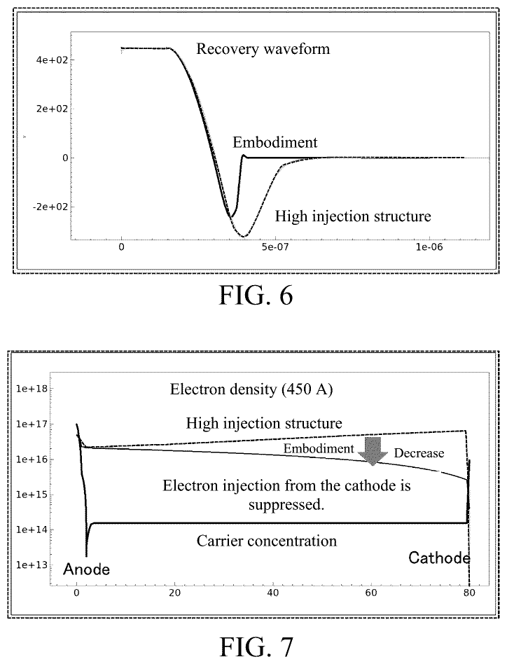

FIG. 6 is a diagram showing a current waveform of the semiconductor device 10 according to the embodiment during recovery. The semiconductor device 10 according to the embodiment and ohmic junction (with high injection of electrons) which is used as a comparative example and in which an N-type high-concentration carrier doped layer is provided adjacent to the cathode electrode are shown. According to this way, it can be seen that in the embodiment, the current amount (Irr) during recovery can be reduced, and the recovery loss can be suppressed.

FIG. 7 is a diagram showing an electron density of the semiconductor device 10 in a depth direction during conduction. Note that, because the electron density is consistent with a hole density according to the law of charge neutrality, FIG. 7 can also be regarded as a diagram showing the hole density. In this way, it can be seen that the electron injection from the cathode electrode 22 is suppressed in the embodiment. Note that, the carrier concentration in the diagram indicates a doping carrier concentration of the N layer 14.

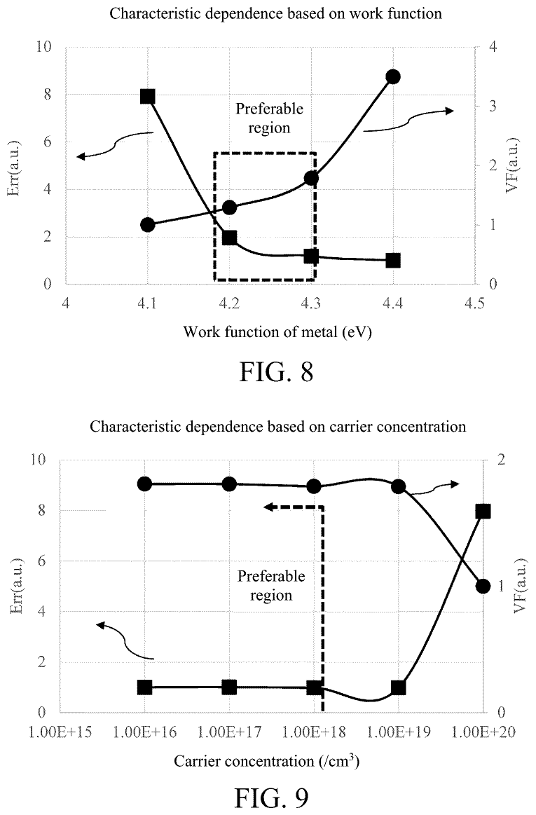

FIG. 8 is a characteristic diagram showing the dependence of the recovery loss Err and the forward voltage drop VF on the work function of the metal. According to this way, if the work function becomes larger, the recovery loss decreases but the forward voltage drop VF increases. It can be seen that both the recovery loss Err and the forward voltage drop VF become lower in the work function ranging from 4.2 to 4.3.

FIG. 9 is a characteristic diagram showing the dependence of the recovery loss Err and forward voltage drop VF on the doping carrier concentration of the N-type carrier (impurity) in the N layer 14. If the carrier concentration becomes higher than a certain degree, the forward voltage drop VF decreases but the recovery loss Err increases. It can be seen that if the carrier concentration is 1×e¹⁸/cm³ or less, both the forward voltage drop VF and the recovery loss Err can be maintained in a stable state. Moreover, in order to maintain the function as a diode, the carrier concentration is preferably set to 1×e¹² or more, and thus it can be seen that the carrier concentration is preferably within the range of 1×e¹² to 1×e¹⁸/cm³.

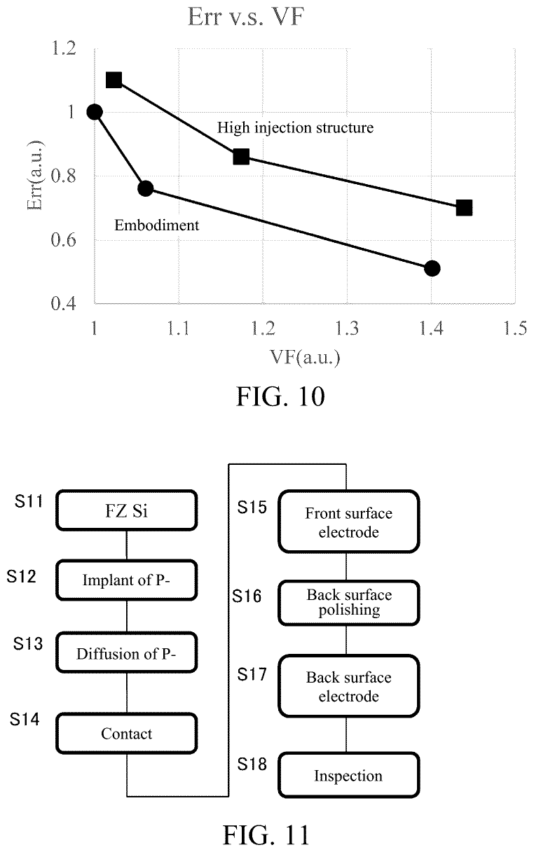

FIG. 10 is a diagram showing a relationship between the recovery loss Err and the forward voltage drop VF of the semiconductor device 10 according to the embodiment during recovery, and further shows a case with general high injection of electrons and short lifetime as a comparative example. In this way, according to the semiconductor device 10 according to the embodiment, a structure with low injection of electrons and long lifetime can be obtained, and the forward voltage drop VF and the recovery loss can be reduced.

<Manufacturing Process>

FIG. 11 is a diagram showing a manufacturing process of the semiconductor device 10 according to the embodiment. First, the semiconductor substrate 12 is prepared (S11). As the semiconductor substrate 12, for example, a substrate used is a floating zone (FZ) silicon wafer and is also an N-type wafer.

A P-type impurity from a front surface side is doped (implanted) (S12) and diffused to form the P layer 16 of P− (S12). Then, a contact is formed (S14), and a front surface electrode, that is, the anode electrode 20, is formed on the front surface (S15).

Then, a back surface side is polished (S16), and a back surface electrode, that is, the cathode electrode 22, is formed by deposition of a metal (S17).

That is, the cathode electrode 22 is directly formed on the N layer 14, and Schottky junction is formed herein.

According to this way, the semiconductor device 10 is formed, various inspections are then performed on the semiconductor device 10 (S18), and after that the manufacturing process ends.

### DESCRIPTION OF THE REFERENCE NUMERALS

10: semiconductor device
12: semiconductor substrate
14: N layer
16: P layer
20: anode electrode
22: cathode electrode

1. A semiconductor device, comprising:
a semiconductor substrate;
an anode electrode, formed on a surface on one side of the semiconductor substrate;
a cathode electrode, formed on a surface on the other side of the semiconductor substrate;
a P layer, formed on the anode electrode side in the semiconductor substrate; and
an N layer, formed on the cathode electrode side in the semiconductor substrate and on the other side of the P layer, wherein
the cathode electrode and the N layer are Schottky functioned,
the cathode electrode is a metal having work function ranging from 4.2 to 4.3, and
the carrier concentration of the N layer ranges from 1×e¹² to 1×e¹⁸/cm³.

2. The semiconductor device according to claim 1, wherein
the metal of the cathode electrode comprises aluminum or an aluminum-silicon alloy as a main component.

3. The semiconductor device according to claim 1, wherein
the semiconductor substrate comprises a silicon wafer.
